(19) United States
(12) Patent Application Publication
(10) Pub. No.: US 2026/0071921 A1
(43) Pub. Date: Mar. 12, 2026

(54) PWM OUTPUT TEMPERATURE SENSING DEVICE, AND DRIVER INCLUDING THE SAME

(71) Applicant: Monolithic Power Systems, Inc., Kirkland, WA (US)

(72) Inventors: Alex Álvarez, Barcelona (ES); Stepan Sutula, Sabadell (ES)

(21) Appl. No.: 18/828,974

(22) Filed: Sep. 9, 2024

(51) Int. Cl. G01K 7/25; H03K 3/017; H03K 17/08; H03K 17/0812

(52) U.S. Cl. CPC G01K 7/25; H03K 3/017; H03K 17/08122; H03K 2017/0806

(57) ABSTRACT

A device includes a periodic exponential decay signal generating circuit and a pulse-width modulated (PWM) generating circuit. The periodic exponential decay signal generating circuit is configured to generate a periodic exponential decay signal. The periodic exponential decay signal continuously and exponentially decays from an upper reference voltage to a lower reference voltage in each period of the periodic exponential decay signal. The PWM generating circuit is configured to receive a temperature response of a thermistor and the periodic exponential decay signal, and to generate, according to the temperature response and the periodic exponential decay signal, a PWM output temperature sensing signal indicating sensed temperature of the thermistor.

### TECHNICAL FIELD OF THE PRESENT INVENTION

The present invention relates to electronic circuits, in particular but not exclusively to PWM output temperature sensing devices for converting temperature response of a thermistor to a pulse width modulation (“PWM”) output, and drivers including such devices.

### BACKGROUND OF THE INVENTION

Thermistors are widely used to sense temperature in automotive and industrial applications. Despite their high sensitivity, thermistors' temperature responses (for example, voltages across the thermistors) are highly non-linear with respect to the sensed temperatures. Different alternatives can be employed to convert the temperature response of the thermistor into temperature values. One of them consists of providing a digital PWM output signal having a duty cycle that carries information of the temperature. However, this solution may need an analog-to-digital architecture (for example, an analog-to-digital converter (ADC)) to convert the temperature response of the thermistor to the digital PWM output and then need a processer to linearize the digital PWM output to obtain the temperature according to a resistance-temperature relation of the thermistor, which may increase the circuit design complexity and production cost.

### SUMMARY OF THE INVENTION

Embodiments of the present invention provide a solution to the problems described above.

In an embodiment, a device includes a periodic exponential decay signal generating circuit and a pulse-width modulated (PWM) generating circuit. The periodic exponential decay signal generating circuit is configured to generate a periodic exponential decay signal. The periodic exponential decay signal continuously and exponentially decays from an upper reference voltage to a lower reference voltage in each period of the periodic exponential decay signal. The PWM generating circuit is configured to receive a temperature response of a thermistor and the periodic exponential decay signal, and to generate, according to the temperature response and the periodic exponential decay signal, a PWM output temperature sensing signal indicating a sensed temperature by the thermistor.

In an embodiment, a driver for driving a power switching device includes: a temperature sensing input pin, a PWM output temperature sensing device, and a temperature sensing output pin. The temperature sensing input pin is coupled to a thermistor to receive a temperature response of the thermistor. The PWM output temperature sensing device is configured to be coupled to the temperature sensing input pin and is configured to generate a PWM output temperature sensing signal indicating sensed temperature by the thermistor according to the temperature response. The temperature sensing output pin is configured to be coupled to the PWM output temperature sensing device and is configured to output the PWM output temperature sensing signal.

In an embodiment, a temperature sensing method includes: generating a periodic exponential decay signal, where the periodic exponential decay signal continuously and exponentially decays from an upper reference voltage to a lower reference voltage in each period of the periodic exponential decay signal; receiving a temperature response of a thermistor and the periodic exponential decay signal, and generating, according to the temperature response and the periodic exponential decay signal, a PWM output temperature sensing signal indicating sensed temperature by the thermistor.

### BRIEF DESCRIPTION OF DRAWINGS

The following drawings are provided to better understand the following description of the embodiments of the present invention, wherein like elements are provided with like reference numerals.

FIG. 1 illustratively shows a block diagram of a PWM output temperature sensing device 100, in accordance with an embodiment of the present application.

FIG. 2 illustratively shows a substantially linear relationship between the duty cycle of the PWM output temperature sensing signal with the temperature.

FIG. 3A illustrates a schematic circuit diagram of an exemplary PWM output temperature sensing device 300A, in accordance with an embodiment of the present application.

FIG. 3B illustrates a schematic circuit diagram of another exemplary PWM output temperature sensing device 300B, in accordance with another embodiment of the present application.

FIG. 4 shows a waveform graph illustrating waveforms of the RC output voltage V_{SW}, the comparison signal CS, the charging/discharging controlling signal SCMD, and the PWM output temperature sensing signal, in accordance with an embodiment of the present application.

FIG. 5 shows a power converter 500 including a PWM output temperature sensing device 511, in accordance with an embodiment of the present application.

FIG. 6 shows a flowchart of temperature sensing method 600, in accordance with an embodiment of the present invention.

In the drawings, the same or corresponding reference numerals are used to indicate the same or corresponding elements.

### DETAILED DESCRIPTION OF THE INVENTION

Hereinafter, specific embodiments of the present invention will be described in detail, and it should be noted that the embodiments described herein are only for illustration and are not intended to limit the present invention. In the following description, numerous specific details are set forth in order to provide a thorough understanding of the present invention. However, it will be apparent to one having ordinary skills in the art that these specific details are not necessary to practice the present invention. In other instances, well-known circuits, materials or methods are not described in detail in order to avoid obscuring the present invention.

Throughout this specification, references to “one embodiment”, “an embodiment”, “one example” or “an example” mean that a particular feature, structure or characteristic described in connection with this embodiment or example is included in at least one embodiment of the present invention. Therefore, the phrases “in one embodiment”, “in an embodiment”, “one example” or “an example” appearing in various places throughout the specification do not necessarily all refer to the same embodiment or example. Furthermore, specific features, structures or characteristics may be combined in any suitable combination and/or sub-combination in one or more embodiments or examples. Furthermore, it should be understood by those skilled in the art that the drawings provided herein are for illustration purposes and are not necessarily drawn to scale. When an element is said to be “coupled” or “connected” to another element, it may be directly coupled or connected to another element, or an intervening element may be present therebetween. Conversely, when an element is said to be “directly coupled” or “directly connected” to another element, there are no intervening elements. Like reference numerals indicate like elements. The term “and/or” as used herein includes any and all combinations of one or more related listed items.

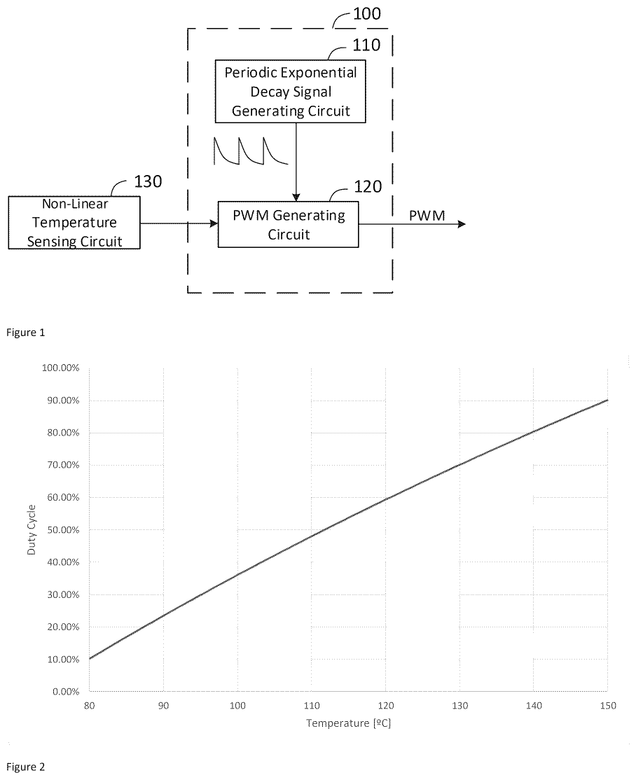

FIG. 1 illustratively shows a block diagram of a PWM output temperature sensing device 100, in accordance with an embodiment of the present application. As shown in FIG. 1, the PWM output temperature sensing device 100 includes a periodic exponential decay signal generating circuit 110 and a PWM generating circuit 120.

The PWM output temperature sensing device 100 is configured to receive a temperature response indicative of a sensed temperature from a non-linear temperature sensing circuit 130 and convert the temperature response into a PWM output temperature sensing signal with a duty cycle that varies based on the sensed temperature.

The non-linear temperature sensing circuit 130 is configured to sense a temperature of an element (for example, a power device in a power management IC) and provide the temperature response carrying information about the sensed temperature of the element being sensed. The temperature response of the non-linear temperature sensing circuit 130 may follow a non-linear response curve in response to a linear change in the temperature. The non-linear response curve may be approximated by an exponential or a logarithmic function.

In an embodiment, the non-linear temperature sensing circuit 130 includes a thermistor (for example, a negative temperature coefficient (“NTC”) thermistor). Generally, the temperature response of the thermistor may be a function of a resistance of the thermistor. For example, the non-linear temperature sensing circuit 130 may have a constant current flowing through the thermistor, and then the temperature response of the non-linear temperature sensing circuit 130 includes a voltage across the thermistor. The voltage across the thermistor has a linear relationship with respect to the resistance of the thermistor. In an embodiment, as shown in FIG. 1, the non-linear temperature sensing circuit 130 is disposed outside the PWM output temperature sensing device 100. In another embodiment, the non-linear temperature sensing circuit 130 may be disposed inside the PWM output temperature sensing device 100 to be part of the PWM output temperature sensing device 100.

As well known to those skilled in the art, a resistance of the NTC thermistor may be closely approximated by the so-called B-Model, which describes the resistance of the NTC thermistor using an exponential function as shown in the following equation (1):

$$\frac{{R}_{NTC}}{{R}_{25}} = exp ( {B}_{25 / 100} ( \frac{1}{T} - \frac{1}{{T}_{25}} ) ) , \qquad ( 1 )$$

where R_{NTC} is the resistance of the NTC thermistor at temperature T in K, R₂₅ is the resistance of the NTC thermistor at temperature T₂₅, T₂₅ is a rated temperature 25C° in K and B_{25/100} is a material-specific constant defined by 25C° and 100C°.

Rearranging the equation (1) to solve for the temperature T gives:

$$\frac{1}{T} = \frac{ln ( \frac{{R}_{NTC}}{{R}_{25}} ) + \frac{{B}_{25 / 100}}{{T}_{25}}}{{B}_{25 / 100}} . \qquad ( 2 )$$

In practical application scenarios, for example, where the non-linear temperature sensing circuit 130 is arranged to sense temperature of an integrated circuit (for example, the aforementioned power management IC or a device therein), a temperature T of the sensed element is usually in a limited range (hereinafter referred to a predefined temperature range). For example, the predefined temperature range includes an operating temperature range of the integrated circuit in which the PWM output temperature sensing device 100 is disposed. In such predefined temperature range, the temperature T may be approximated by a Napierian Logarithmic function expressed as the following equation (3):

$$T = {k}_{1} ln ( {R}_{NTC} ) + {k}_{2} , \qquad ( 3 )$$

where k₁ and k₂ are constant values.

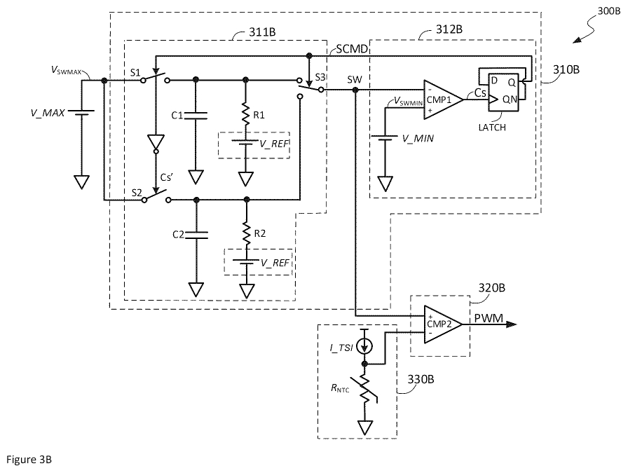

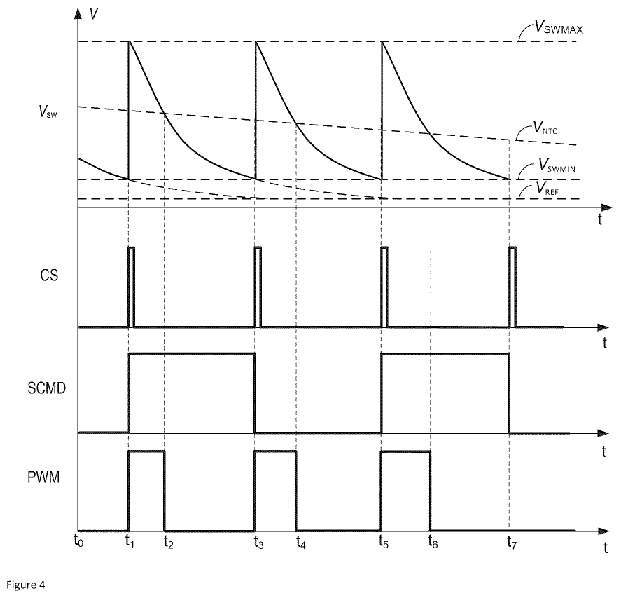

The periodic exponential decay signal generating circuit 110 is configured to generate a periodic exponential decay signal. For example, the periodic exponential decay signal periodically decays from an upper reference voltage to a lower reference voltage, and a decay waveform in each period may be approximated by an exponential function. The details about generation of this periodic exponential decay signal will be described with reference to FIGS. 3A, 3B, and 4.

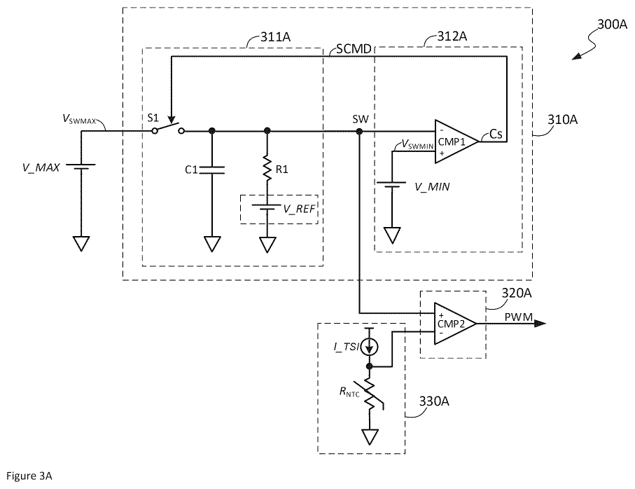

The PWM generating circuit 120 is configured to receive the temperature response from the non-linear temperature sensing circuit 130 and the periodic exponential decay signal from the periodic exponential decay signal generating circuit 110. The PWM generating circuit 120 is configured to convert the temperature response of the non-linear temperature sensing circuit 130 to a PWM output temperature sensing signal based on the periodic exponential decay signal. The duty cycle of the PWM output temperature sensing signal varies with the sensed temperature by the non-linear temperature sensing circuit 130, while a period of the PWM output temperature sensing signal is equal to that of the periodic exponential decay signal. As shown in FIG. 2, the duty cycle of the PWM output temperature sensing signal approximately follows a linear response curve in response to a linear change in the temperature in the predefined temperature range. The linear response curve may be approximated by a linear function.

FIG. 3A illustrates a schematic circuit diagram of an exemplary PWM output temperature sensing device 300A, in accordance with an embodiment of the present application. The PWM output temperature sensing device 300A is an embodiment of the PWM output temperature sensing device 100 shown in FIG. 1.

As shown in FIG. 3A, the PWM output temperature sensing device 300A includes a periodic exponential decay signal generating circuit 310A and a PWM generating circuit 320A. The periodic exponential decay signal generating circuit 310A and the PWM generating circuit 320A are embodiments of the periodic exponential decay signal generating circuit 110 and the PWM generating circuit 120 shown in FIG. 1, respectively.

The periodic exponential decay signal generating circuit 310A includes a resistance-capacitance (RC) circuit 311A and a charge/discharge controlling circuit 312A. The RC circuit 311A includes an output terminal (also referred to as a RC output terminal) SW configured to provide an output voltage (also referred to as a RC output voltage) V_{SW} of the RC circuit 311A.

In an embodiment, the RC circuit 311A includes at least a capacitor C1 and a resistor R1. In an embodiment, as shown in FIG. 3A, the capacitor C1 and the resistor R1 are connected in parallel between a power supply V_MAX and a reference ground. In another embodiment, the RC circuit 311A may further (but not necessarily) include a reference power supply V_REF connected in series with the resistor R1, such that additional flexibility may be provided for design in case the application demands specific voltage requirements/limits for an upper reference voltage and a lower reference voltage. In the following description, the reference power supply V_REF is omitted for the ease of description.

Specifically, as shown in FIG. 3A, the RC circuit 311A further includes a switch S1. The switch S1 can be alternately turned on and off under control of the charge/discharge controlling circuit 312A, so as to alternately charge and discharge the capacitor C1. For example, when the switch S1 is turned on, the power supply V_MAX charges the capacitor C1 to an upper reference voltage V_{SWMAX}, and when the switch S1 is turned off, the capacitor C1 discharges through the resistor R1. In the embodiment shown in FIG. 3A, the RC output voltage V_{SW} of the RC circuit 311A equals to the voltage across the capacitor C1.

According to characteristics of capacitors, when the capacitor C1 is discharging, the voltage across the capacitor C1 follows an exponential curve with respect to a discharging time. Therefore, by periodically charging and discharging the RC circuit 311A, while minimizing the charging time to a relatively short/negligible time, the output voltage V_{SW} of the RC circuit 311A can be approximated by a periodic curve which continuously and exponentially decays from the upper reference voltage to the lower reference voltage.

The charge/discharge controlling circuit 312A compares the RC output voltage V_{SW} with the lower reference voltage V_{SWMIN}, and provides a comparison signal CS on the output terminal. In the embodiment shown in FIG. 3A, the comparison signal CS is used as a charging/discharging controlling signal SCMD, for controlling the charging and discharging of the capacitor C1 in the RC circuit 311A. For example, when the RC output voltage V_{SW} decays to be lower than the lower reference voltage V_{SWMIN}, the comparator CMP1 changes the comparison signal CS to a first CS logic state (for example, logic high). In response to the comparison signal CS changing to the first CS logic state (for example, logic high), the switch S1 is turned on to connect the upper power supply V_MAX to the capacitor C1 and the first input terminal (for example, an inverting input terminal) of the comparator CMP1. Then the capacitor C1 is charged to the upper reference voltage V_{SWMAX}. Since the first input terminal of the comparator CMP1 is connected to the RC circuit 311A, the comparison signal CS is changed to a second CS logic state (for example, logic low) after a short period to turn off the switch S1 and starts to discharge the capacitor C1 again. A rising delay may exist for the RC output voltage V_{SW} to rise from the lower reference voltage V_{SWMIN} to the upper reference voltage V_{SWMAX}. However, the rising delay is relatively small compared to the discharging time for the capacitor C1 to be discharged from the upper reference voltage V_{SWMAX} to the lower reference voltage V_{SWMIN}. Therefore, the RC output voltage V_{SW} may be approximated by a periodic exponential decay function which continuously and periodically decays from the upper reference voltage V_{SWMAX} to the lower reference voltage V_{SWMIN}.

The charge/discharge controlling circuit 312A includes a comparator CMP1. The comparator CMP1 includes a first input terminal (for example, an inverting input terminal), a second input terminal (for example, a non-inverting input terminal), and an output terminal. The first input terminal is connected to the RC output terminal SW of the RC circuit 311A to receive the RC output voltage V_{SW}, and the second input terminal is connected to a lower power supply V_MIN to receive a lower reference voltage V_{SWMIN}. In an embodiment, as shown in FIG. 3A, the lower power supply V_MIN is disposed inside the charge/discharge controlling circuit 312A (and the PWM output temperature sensing device 300) to be a part of the charge/discharge controlling circuit 312A (and the PWM output temperature sensing device 300). In another embodiment, the lower power supply V_MIN may be disposed outside the PWM output temperature sensing device 300.

The periodic exponential decay signal generating circuit 310A shown in FIG. 3A is only provided as an example, and the present invention is not so limited. In other embodiments, the periodic exponential decay signal generating circuit 310A includes any architecture capable of providing the periodic exponential decay signal.

In an embodiment, the upper reference voltage V_{SWMAX} and the lower reference voltage V_{SWMIN} are determined according to a temperature range of the thermistor, the constant current provided to the thermistor, voltage ratings and duty cycle extreme values, just to name a few examples.

In an embodiment, the PWM generating circuit 320A includes a comparator CMP2. As shown in FIG. 3A, the comparator CMP2 includes a first input terminal (for example, a non-inverting input terminal), a second input terminal (for example, an inverting input terminal), and an output terminal. The first input terminal is connected to the RC circuit 311A to receive the RC output voltage V_{SW}, and the second input terminal is connected to a non-linear temperature sensing circuit 330A to receive a temperature response of the non-linear temperature sensing circuit 330A. In an embodiment, as shown in FIG. 3A, the non-linear temperature sensing circuit 330A includes a constant current source I_TSI and a thermistor R_{NTC}. In this embodiment, the temperature response includes a voltage V_{NTC} across the thermistor R_{NTC}. The comparator CMP2 compares the RC output voltage V_{SW} with the voltage V_{NTC} and provides a PWM output temperature sensing signal on the output terminal. For example, during each discharging process of the capacitor C1, the RC output voltage V_{SW} (or the voltage across the capacitor C1) decreases from the upper reference voltage V_{SWMAX} to the lower reference voltage V_{SWMIN}. When the RC output voltage V_{SW} is higher than the voltage V_{NTC}, the comparator CMP2 sets the PWM output temperature sensing signal to a first PWM logic state (for example, logic high), and when the RC output voltage V_{SW} falls below the voltage V_{NTC}, then the comparator CMP2 changes the PWM output temperature sensing signal to a second PWM logic state (for example, logic low).

For a RC circuit, it is known that a voltage across the capacitor (for example, the capacitor C1) as a function of time during discharging is defined as:

$${V}_{SW} ( t ) = {V}_{REF} + ( {V}_{SWMAX} - {V}_{REF} ) \cdot exp ( \frac{- t}{RC} ) \qquad ( 4 )$$

where V_{SW} (t) is a voltage across a capacitor (for example, the capacitor C1) at time t, VREF is a reference voltage connected in series with a resistor (for example, the resistor R1) in the RC circuit, V_{SWMAX} is an initial voltage across the capacitor before discharging, and RC is a time constant of the RC circuit (for example, the RC circuit 311A).

We can know that:

$${V}_{SW} ( t = P ) = {V}_{SWMIN} , and \qquad ( 5 )$$

$${V}_{SW} ( t = D \cdot P ) = {V}_{NTC} , \qquad ( 6 )$$

where P represents a period of the RC output voltage V_{SW} (which also equals to the period of the PWM output temperature sensing signal), D represents the duty cycle of the PWM output temperature sensing signal.

Then it can be proven that the duty cycle D of the PWM output temperature sensing signal follows the following relationship:

$$D = ln ( \frac{{V}_{NTC} - {V}_{REF}}{{V}_{SWMAX} - {V}_{REF}} ) / ln ( \frac{{V}_{SWMIN} - {V}_{REF}}{{V}_{SWMAX} - {V}_{REF}} ) . \qquad ( 7 )$$

Therefore, the duty cycle of the PWM output temperature sensing signal follows a Napierian Logarithmic function with respect to the voltage V_{NTC} of the thermistor R_{NTC}. Referring back to the equation (3), in which the temperature T may be approximated by a logarithmic function in a limited temperature range, the relation between the duty cycle of the PWM output temperature sensing signal and the temperature may be approximated by a linear function.

As previously mentioned, a short period of rising time may exist from a time when the RC output voltage V_{SW} falls below the lower reference voltage V_{SWMIN} to a time when the RC output voltage V_{SW} rises back to the upper reference voltage V_{SWMAX}. In order to further reduce the delay time, the present invention further proposes another PWM output temperature sensing device as shown in FIG. 3B.

FIG. 3B illustrates a schematic circuit diagram of another exemplary PWM output temperature sensing device 300B, in accordance with another embodiment of the present application.

As compared with FIG. 3A, the RC circuit 311B shown in FIG. 3B further includes a capacitor C2 and a resistor R2 in addition to the capacitor C1 and the resistor R1 and the charge/discharge controlling circuit 312B further includes a latch LATCH. As shown in FIG. 3B, the capacitor C2 and the resistor R2 are also connected in parallel between the power supply V_MAX and the reference ground. The capacitor C2 is the same as the capacitor C1, and the resistor R2 is the same as the resistor R1.

When one capacitor (for example, the capacitor C1) is during discharging process, another capacitor (for example, the capacitor C2) can be charged to the upper reference voltage V_{SWMAX}. Specifically, the RC circuit 311B further includes a switch S2 coupled between the upper power supply V_MAX and the parallelly connected capacitor C2 and resistor R2. The switch S1 and the switch S2 are alternately turned on and turned off through a charging/discharging controlling signal SCMD provided from the charge/discharge controlling circuit 312B and its inverted signal SCMD′. In an embodiment, the RC circuit 311B further includes a multiplexer switch S3, which can selectively connect the RC output terminal SW to one capacitor of the capacitors C1 and C2 to receive a voltage across that one capacitor under control of the charging/discharging controlling signal SCMD. In an example, when the RC output terminal SW is connected to the capacitor C1 and when the voltage on the capacitor C1 falls below the lower reference voltage V_{SWMIN}, the comparator CMP1 changes a comparison signal CS from a second CS logic state (for example, logic low) to a first CS logic state (for example, logic high). The latch LATCH receives the comparison signal CS and generates/provides the charging/discharging controlling signal SCMD according to the comparison signal CS. In an embodiment, as shown in FIG. 3B, the latch LATCH is a D latch. In another embodiment, the latch LATCH is a R-S latch. The present is not so limited. In response to the comparison signal CS changing from the second CS logic state (for example, logic low) to the first CS logic state (for example, logic high), the latch LATCH changes a logic state of the charging/discharging controlling signal SCMD (for example, from logic high to logic low or from logic low to logic high).

In response to the charging/discharging controlling signal SCMD changing to a first SCMD logic state (for example, logic high), the switch S1 is turned on, the switch S2 is turned off, and the switch S3 connects the RC output terminal SW to a lower port, for example, to the capacitor C2. Then the upper reference voltage V_{SWMAX} is removed from the capacitor C2 and connected to the capacitor C1 to charge the capacitor C1, and the capacitor C2 starts to discharge. In response to the charging/discharging controlling signal SCMD changing to a second SCMD logic state (for example, logic low), the switch S1 is turned off, the switch S2 is turned on, and the switch S3 connects the RC output terminal SW to an upper port, for example, to the capacitor C1. Then the upper reference voltage V_{SWMAX} is removed from the capacitor C1 and connected to the capacitor C2 to charge the capacitor C2, and the capacitor C1 starts to discharge. Therefore, when one capacitor is charging, the other capacitor is discharging. The delay time from the time when the RC output voltage V_{SW} falls below the lower reference voltage V_{SWMIN} to the time when the RC output voltage V_{SW} rises back to the upper reference voltage V_{SWMAX} can be further reduced.

FIG. 4 shows a waveform graph illustrating waveforms of the RC output voltage V_{SW}, the comparison signal CS, the charging/discharging controlling signal SCMD, and the PWM output temperature sensing signal, in accordance with an embodiment of the present application. FIG. 4 is described in combination with FIG. 3B.

As shown in FIG. 4, the RC output voltage V_{SW} on the RC output terminal SW of the RC circuit 311B periodically decays from the upper reference voltage V_{SWMAX} to the lower reference voltage V_{SWMIN}, and the voltage V_{NTC} of the thermistor R_{NTC} decreases along with time, that is, the temperature sensed by the thermistor R_{NTC} increases with time.

From time t0 to time t1, the RC output voltage V_{SW} is higher than the lower reference voltage V_{SWMIN}. The charging/discharging controlling signal SCMD is at logic low, the switch S1 is off, the switch S2 is on, and the switch S3 connects the RC output terminal SW to the upper port, for example, to the capacitor C1, and the capacitor C1 is discharging. At the time t1, the RC output voltage V_{SW} decays to be lower than the lower reference voltage V_{SWMIN}, the comparator CMP1 sets the comparison signal CS to logic high. In response to the comparison signal CS becoming logic high, the latch IATCH sets the charging/discharging controlling signal SCMD from logic low to logic high. In response to the charging/discharging controlling signal SCMD changing to logic high, the switch S1 is turned on, the switch S2 is turned off, and the switch S3 connects the RC output terminal SW to the lower port, for example, to the capacitor C2. The upper reference voltage V_{SWMAX} is removed from the capacitor C2 and connected to the capacitor C1 to charge the capacitor C1. The capacitor C2 starts to discharge. Since the capacitor C2 has been pre-charged to the upper reference voltage V_{SWMAX}, the RC output voltage V_{SW} then immediately rises back to the upper reference voltage V_{SWMAX}. Shortly after the RC output voltage V_{SW} increases from the lower reference voltage V_{SWMIN} to the upper reference voltage V_{SWMAX}, the comparator CMP1 changes the comparison signal CS to logic low. Between the time t1 to t2, the RC output voltage V_{SW} is higher than the voltage V_{NTC} of the thermistor R_{NTC}, and the PWM output temperature sensing signal remains at logic high. At the time t2, the RC output voltage V_{SW} becomes lower than the voltage V_{NTC} of the thermistor R_{NTC}, and the PWM generating circuit 320B changes the PWM output temperature sensing signal from logic high to logic low. At time t3, the RC output voltage V_{SW} becomes lower than the lower reference voltage V_{SWMIN}. At this time, the comparator CMP1 changes the comparison signal CS to logic high. In response to the comparator CMP1 becoming logic high, the latch IATCH sets the charging/discharging controlling signal SCMD from logic high to logic low, the switch S1 is turned off, the switch S2 is turned on, and the switch S3 connects the RC output terminal SW to the higher port, for example, to the capacitor C1. Since the capacitor C1 is pre-charged to the upper reference voltage V_{SWMAX}, the RC output voltage V_{SW} rises back to the upper reference voltage V_{SWMAX} immediately, and a new cycle of the RC output voltage V_{SW} begins.

As can be seen from FIG. 4, the duty cycle of the PWM output temperature sensing signal increases as the voltage V_{NTC} of the thermistor R_{NTC} decreases. According to the relationship between the voltage and the temperature sensed by the thermistor, it can be known that the duty cycle of the PWM output temperature sensing signal increases as the temperature increases.

The PWM output temperature sensing device according to the embodiments of the present invention can provide a PWM output temperature sensing signal with a duty cycle being linear to the temperature with a relatively simple circuit structure. Compared to the aforementioned ADC solution in which the analog temperature response is converted by an ADC converter to digital PWM signal, the system complexity can be significantly reduced. Moreover, since the duty cycle of the PWM output temperature sensing signal provided by the PWM output temperature sensing device according to the embodiments of the present invention is substantially linear with respect to the temperature, it may be directly used to indicate the temperature value of the thermistor without further linearization processing.

Temperature is critical for integrated circuit (IC) chips. The IC chips usually need to perform controlling based on temperature information about the temperature sensed by the thermistor, not only to prevent damage or failure caused by the over-temperature, but also to keep the IC chips to stay in a specified operating temperature range to ensure good performance.

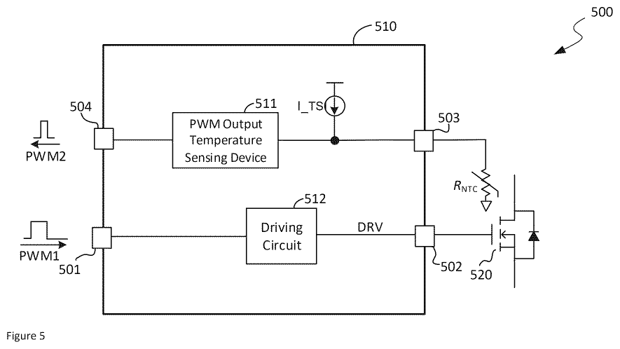

FIG. 5 shows a power converter 500 including a PWM output temperature sensing device 511, in accordance with an embodiment of the present application. The PWM output temperature sensing device 511 is an embodiment of the abovementioned PWM output temperature sensing devices 100, 300A or 300B. It should be understood that the power converter 500 shown in FIG. 5 is only provided as an example, and the PWM output temperature sensing device according to the present invention can be applied to any suitable integrated circuit which needs to perform controlling based on the temperature information.

As shown in FIG. 5, the power converter 500 includes a driver 510, a power switching device 520, and a thermistor R_{NTC}. Referring to FIG. 5, in an embodiment, the driver 510 and the power switching device 520 is integrated on different ICs. In another embodiment, the driver 510 and the power switching device 520 is integrated on a same IC. The thermistor R_{NTC} is arranged on the same IC with and close to the power switching device 520 to sense temperature of the power switching device 520.

In an embodiment, the driver 510 is adapted for driving the power switching device 520. In an embodiment, as shown in FIG. 5, the driver 510 includes a first input pin 501, a first output pin 502, a temperature sensing input pin 503, a temperature sensing output pin 504, the PWM output temperature sensing device 511, a driving circuit 512, and a constant current source I_TSI. The circuit structure of the driver 510 is not limited to the embodiment shown in FIG. 5.

The first input pin 501 is configured to receive a switching control signal PWM1. The driving circuit 512 is configured to generate a driving signal DRV according to the switching control signal PWM1 received through the first input pin 501. The first output pin 502 is coupled to a control terminal of the power switching device 520. The driving signal DRV is output to the control terminal of the power switching device 520 through the first output pin 502. The thermistor R_{NTC} is coupled to the constant current source I_TSI to receive a constant current from the constant current source I_TSI. The constant current source I_TSI shown in FIG. 5 is disposed inside the driver IC 510. It should be understood that the constant current source I_TSI may also be disposed outside the driver IC 510. A temperature response (for example, a voltage across the thermistor R_{NTC}) of the thermistor R_{NTC} is transmitted to the PWM output temperature sensing device 511 through the temperature sensing input pin 503, and the PWM output temperature sensing device 511 generates a PWM output temperature sensing signal PWM2 according to the temperature response of the thermistor R_{NTC}. The PWM output temperature sensing signal PWM2 includes temperature information about the temperature sensed by the thermistor R_{NTC}. In an embodiment, the PWM output temperature sensing signal PWM2 substantially has a duty cycle which follows a linear response curve in response to a linear change in the sensed temperature by the thermistor R_{NTC} (that is, the temperature of the power switching device 520) in a predefined temperature range. In an embodiment, the linear response curve may be approximated by a linear function.

In an embodiment, the PWM output temperature sensing signal PWM2 is further transmitted to a control circuit (not shown) of the power converter 500 through the temperature sensing output pin 504, so that the control circuit may use it to perform controlling of the power switching device 520 accordingly.

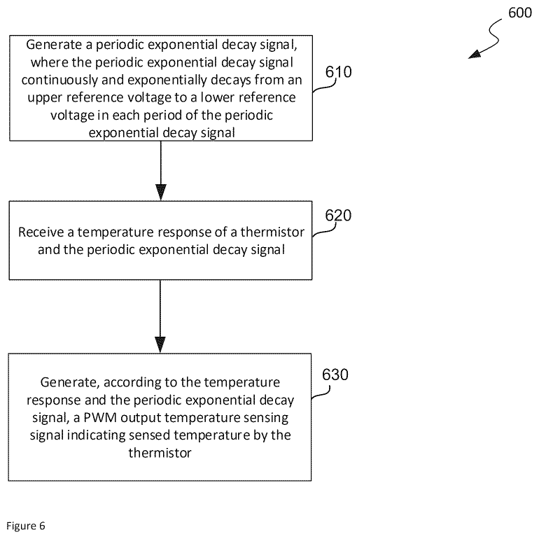

FIG. 6 shows a flowchart of temperature sensing method 600, in accordance with an embodiment of the present invention. The method 600 is performed by any one of the aforementioned PWM output temperature sensing device 100, 300A, 300B, and 511. As previously stated, each of the PWM output temperature sensing device 100, 300A, 300B, and 511 includes a periodic exponential decay signal generating circuit (for example, 110, 310A or 310B) and a PWM generating circuit (for example, 120, 320A or 320B).

In block 610, the exponential decay signal generating circuit generates a periodic exponential decay signal, where the periodic exponential decay signal continuously and exponentially decays from an upper reference voltage to a lower reference voltage in each period of the periodic exponential decay signal.

In block 620, the PWM generating circuit receives a temperature response of a thermistor and the periodic exponential decay signal.

In block 630, the PWM generating circuit generates, according to the temperature response and the periodic exponential decay signal, a PWM output temperature sensing signal indicating sensed temperature by the thermistor.

In an embodiment, a duty cycle of the PWM output temperature sensing signal is substantially linear with respect to the sensed temperature by the thermistor in a predefined temperature range.

Although the flowchart of FIG. 6 shows sequential actions. It is obvious to persons skilled the art that these actions could be performed in any order.

As previously stated, the circuit structure of the PWM output temperature sensing device according to the embodiments of the present invention is much simpler than the existing ADC solution. Thus, it may save a lot of silicon area and consumption and reduce the system complexity when the PWM output temperature sensing device is implemented on an IC (for example, the diver IC 510). Moreover, since the duty cycle of the PWM output temperature sensing signal provided by the PWM output temperature sensing device according to the embodiments of the present invention is linear, no discrete components at PCB level are ever needed to linearize the digital PWM signal provided by the traditional ADC.

Although the present invention has been described with reference to several exemplary embodiments, it should be understood that the terminology used herein is illustrative and exemplary rather than limiting. As the present invention can be embodied in various forms without departing from the spirit or essence of the present invention, it should be understood that the above-mentioned embodiments are not limited to any of the foregoing details, but should be broadly interpreted within the spirit and scope defined by the appended claims, and therefore all changes and modifications that fall within the scope of the claims or their equivalents are intended to be covered by the appended claims.

What is claimed is:

1. A device, comprising:
a periodic exponential decay signal generating circuit, configured to generate a periodic exponential decay signal, wherein said periodic exponential decay signal continuously and exponentially decays from an upper reference voltage to a lower reference voltage in each period of said periodic exponential decay signal; and
a pulse-width modulated (PWM) generating circuit, configured to receive a temperature response of a thermistor and said periodic exponential decay signal, and to generate, according to said temperature response and said periodic exponential decay signal, a PWM output temperature sensing signal indicating a sensed temperature by said thermistor.

2. The device of claim 1, wherein said PWM generating circuit is configured to compare said periodic exponential decay signal with said temperature response and provide said PWM output temperature sensing signal according to a comparison result of comparing said periodic exponential decay signal with said temperature response.

3. The device of claim 2, wherein said PWM generating circuit comprises a first comparator, and wherein the first comparator has a first input terminal configured to receive said periodic exponential decay signal, a second input terminal configured to receive said temperature response, and an output terminal configured to provide said PWM output temperature sensing signal.

4. The device of claim 1, wherein said periodic exponential decay signal generating circuit comprises:
a resistance-capacitance (RC) circuit comprising a first capacitor and a first resistor connected in parallel between an upper power supply and a reference ground, and
an RC output terminal configured to provide an output voltage of said RC circuit.

5. The device of claim 4, wherein said periodic exponential decay signal generating circuit further comprises a charge/discharge controlling circuit, configured to control charging and discharging of said first capacitor in said RC circuit.

6. The device of claim 5, wherein said charge/discharge controlling circuit is configured to compare said output voltage on said RC output terminal with said lower reference voltage, and provide, according to a comparison result of comparing said output voltage on said RC output terminal with said lower reference voltage, a charge/discharge controlling signal to control charging and discharging of said first capacitor in said RC circuit, so as to provide said periodic exponential decay signal on said RC output terminal.

7. The device of claim 6, wherein said charge/discharge controlling circuit comprises a second comparator.

8. The device of claim 6, wherein said RC output terminal is connected to said parallelly connected first capacitor and first resistor to receive a voltage across said first capacitor, wherein when said output voltage on said RC output terminal becomes lower than said lower reference voltage, said charge/discharge controlling circuit provides said charge/discharge controlling signal to charge said first capacitor to said upper reference voltage by said upper power supply, and when said output voltage on said RC output terminal increases from said lower reference voltage to said upper reference voltage, said charge/discharge controlling circuit provides said charge/discharge controlling signal to discharge said first capacitor.

9. The device of claim 8, wherein said RC circuit further comprises a first switch connected between said upper power supply and the parallelly connected first capacitor and first resistor, and wherein when said output voltage on said RC output terminal becomes lower than said lower reference voltage, said charge/discharge controlling circuit provides said charge/discharge controlling signal to turn on said first switch to connect said upper power supply to said first capacitor so as to charge said first capacitor to said upper reference voltage, and when said output voltage on said RC output terminal becomes higher than said lower reference voltage, said charge/discharge controlling circuit provides said charge/discharge controlling signal to turn off said first switch to disconnect said upper power supply from said first capacitor and to discharge said first capacitor.

10. The device of claim 6, wherein said RC circuit further comprises a second capacitor and a second resistor connected in parallel between said upper power supply and said reference ground, and wherein said charge/discharge controlling circuit is configured to provide said charge/discharge controlling signal to control charging and discharging of said first capacitor and said second capacitor, and wherein when one of said first capacitor and said second capacitor is discharging, another capacitor of said first capacitor and said second capacitor is charged to said upper reference voltage.

11. The device of claim 10, wherein said RC output terminal is connected to one capacitor of said first capacitor and said second capacitor to receive a voltage across said one capacitor, and wherein when said output voltage on said RC output terminal becomes lower than said lower reference voltage, said charge/discharge controlling circuit provides said charge/discharge controlling signal to connect said RC output terminal to another capacitor of said first capacitor and said second capacitor to receive a voltage across said another capacitor.

12. The device of claim 10, wherein said RC circuit further comprises a second switch coupled between said upper power supply and the parallelly connected second capacitor and second resistor, and a multiplexer switch for selectively connect said RC output terminal to one of said first capacitor and said second capacitor.

13. The device of claim 12, wherein a duty cycle of said PWM output temperature sensing signal is linear with respect to said sensed temperature in a predefined temperature range.

14. The device of claim 1, wherein said thermistor is a negative temperature coefficient (NTC) thermistor.

15. The device of claim 1, wherein the temperature response of the thermistor comprises a voltage across the thermistor.

16. A driver for driving a power switching device, comprising:
a temperature sensing input pin, configured to be coupled to a thermistor to receive a temperature response of said thermistor,
a PWM output temperature sensing device, configured to be coupled to said temperature sensing input pin, and generate a PWM output temperature sensing signal indicating sensed temperature by said thermistor according to said temperature response; and
a temperature sensing output pin, configured to be coupled to said PWM output temperature sensing device, and configured to output said PWM output temperature sensing signal.

17. The driver of claim 16, wherein said PWM output temperature sensing device comprises:
a periodic exponential decay signal generating circuit, configured to generate a periodic exponential decay signal, wherein said periodic exponential decay signal continuously and exponentially decays from an upper reference voltage to a lower reference voltage in each period of said periodic exponential decay signal; and
a pulse-width modulated (PWM) generating circuit, configured to receive a temperature response of a thermistor and said periodic exponential decay signal, and to generate, according to said temperature response and said periodic exponential decay signal, said PWM output temperature sensing signal indicating said sensed temperature.

18. The driver of claim 17, wherein said PWM generating circuit is configured to compare said periodic exponential decay signal with said temperature response and provide said PWM output temperature sensing signal according to a comparison result of comparing said periodic exponential decay signal with said temperature response.

19. The driver of claim 17, wherein said periodic exponential decay signal generating circuit comprises:
a resistance-capacitance (RC) circuit comprising a first capacitor and a first resistor connected in parallel between an upper power supply and a reference ground, and
an RC output terminal configured to provide an output voltage of said RC circuit.

20. A temperature sensing method, comprising:
generating a periodic exponential decay signal, wherein said periodic exponential decay signal continuously and exponentially decays from an upper reference voltage to a lower reference voltage in each period of said periodic exponential decay signal;
receiving a temperature response of a thermistor and said periodic exponential decay signal, and
generating, according to said temperature response and said periodic exponential decay signal, a PWM output temperature sensing signal indicating sensed temperature by said thermistor.
